(19) United States
(12) Patent Application Publication
(10) Pub. No.: US 2007/0126451 A1
(43) Pub. Date: Jun. 7, 2007

(54) Method for testing the quality of light-permeable thin film

(75) Inventor: Wei-Chung Chang, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD, Tu-Cheng City (TW)

(21) Appl. No.: 11/454,551

(22) Filed: Jun. 16, 2006

(30) Foreign Application Priority Data
Nov. 25, 2005 (CN) 200510101779.7

(51) Int. Cl. G01R 31/26

(52) U.S. Cl. 324/765

(57) ABSTRACT

An exemplary method for testing the quality of light-permeable thin films includes the steps of: providing a testing pattern; obtaining an image of the testing pattern as a reference image with an image sensor through a reference light-permeable thin film; determining resolution of the reference image by a modulation transfer function; obtaining an image of the testing pattern as a testing image with the image sensor through a to-be-checked light-permeable thin film; determining resolution of the testing image by a modulation transfer function; comparing the determined resolution of the testing image with that of the reference image so as to decide whether the to-be-checked light-permeable thin film is flawed.

### TECHNICAL FIELD

The present invention relates to methods for quality control, and more particularly to a method for testing the quality of a light-permeable thin film.

### BACKGROUND

After being processed by a washing process, surfaces of light-permeable thin films, e.g. transparent optical thin film maybe have flaws thereon, such as dirty particles, scuffing, or water waves. Thus, the thin film needs to be checked so as to determine whether the thin film is flawed.

Typical methods for testing the quality of light-permeable thin films usually consist of either shining a light through the film to highlight flaws or using an amplifying lens to aid an operator to observe them. However, the operator generally has to use experience to determine whether the film is flawed, and as a result different operators produce different results and quality control suffers as a result.

Another typical method for quality-controlling light-permeable thin films uses a charge coupled device (CCD) sensor or a complementary metal-oxide semiconductor (CMOS) sensor and an amplifying lens to obtain electronic images of the film to allow an operator to observe the image so as to determine whether the thin film is flawed or not. This method could potentially be operated automatically by a computer. However, the standard operation criteria are hard to draft, factors such as size of the dirt particles, size of scuffing, or type of the water waves all being problematic.

What is needed, therefore, is a method for testing the quality of light-permeable thin films in a manner that makes the criterion easy to draft.

### SUMMARY

In a preferred embodiment, a method for testing the quality of light-permeable thin film includes the steps in no particular order of: providing a testing pattern; obtaining an image of the testing pattern as a reference image with an image sensor through a reference light-permeable thin film; determining resolution of the reference image by a modulation transfer function; obtaining an image of the testing pattern as a testing image with the image sensor through a to-be-checked light-permeable thin film; determining resolution of the testing image by a modulation transfer function; comparing the determined resolution of the testing image with that of the reference image so as to decide whether the to-be-checked light-permeable thin film is flawed.

Other advantages and novel features will become more apparent from the following detailed description of the present method for testing the quality of light-permeable thin film when taken in conjunction with the accompanying drawings.

### BRIEF DESCRIPTION OF THE DRAWINGS

Many aspects of the method for testing the quality of light-permeable thin film can be better understood with reference to the following drawings. The components in the drawings are not necessarily drawn to scale, the emphasis instead being placed upon clearly illustrating the principles of the present invention. Moreover, in the drawings, like reference numerals designate corresponding parts throughout the several views.

FIG. 1 is a flowchart of a method for testing the quality of light-permeable thin film, in accordance with a preferred embodiment; and

FIG. 2 is a schematic view of an assembly for obtaining a reference image of a testing pattern, in accordance with the preferred embodiment.

### DETAILED DESCRIPTION OF PREFERRED EMBODIMENT

Reference will now be made to the drawing figures to describe the preferred embodiment of the present method for testing the quality of light-permeable thin film in detail.

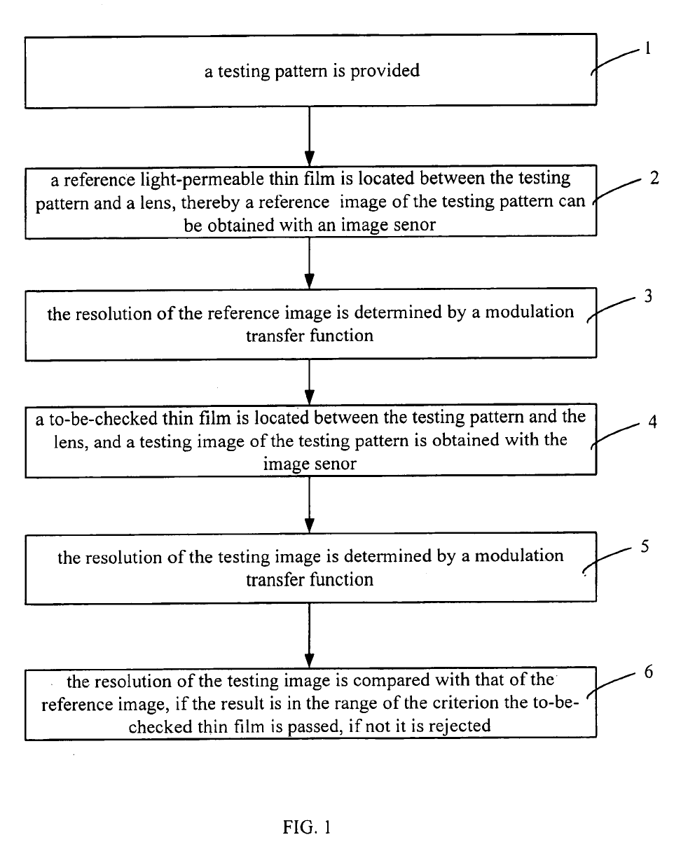

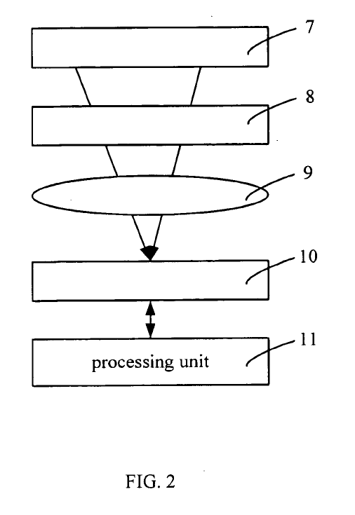

Referring to FIGS. 1 to 2, a method for testing the quality of light-permeable thin film in accordance with a preferred embodiment is shown. The method is described in detail below.

In step 1, a testing pattern is provided. The testing pattern labeled with 7 may have a number of waves thereon. The waves of the pattern testing 7 are either sine waves or square waves. The testing pattern 7 is located on a work table, thus making checking easy.

In step 2, a reference light-permeable thin film is located between the testing pattern and a lens, thereby a reference image of the testing pattern can be obtained with an image sensor.

The reference light-permeable thin film is presumed to have no flaws, having already been checked using a typical method such as, for example, using an amplifying lens to check for flaws. The reference image is achieved via an assembly as described in FIG. 2. The assembly includes a lens 9, an image sensor 10, and a processing unit 11. The reference light-permeable thin film labeled with 8 is located between the testing pattern 7 and the lens 9. The image sensor 10 creates a reference image of the testing pattern 7 through the thin film 8 and the lens 9.

The image sensor 10 is either a CCD sensor or a CMOS sensor connected with the processing unit 11 through, for example, a serial interface, universal serial bus (USB), or 1394 interface. The reference image taken by the image sensor 10 is inputted into the processing unit 11 in real time. The processing unit 11 can also control the image sensor 10 to capture images of the testing pattern 7.

The processing unit 11 is a programmable device, such as a computer, an image analyzer.

In step 3, the resolution of the reference image is determined/characterized by a modulation transfer function.

The reference image is inputted into the processing unit 11 and the resolution is processed. According to types of programs embedded in the processing unit 11, the resolution of the reference image may be determined by either a modulation transfer function (MTF) or a contrast transfer function (CTF). In this embodiment, resolution of the reference image is determined by an MTF. The CTF processes information in a similar way to that of the MTF.

The reference image is divided into a number of regions, for example, 2ⁿ (n is an integer equal to or larger than 1). The resolution of each region labeled with MTFₙ (n is equal to 1, 2, 3, . . . n) is determined by the modulation transfer function. Therefore, the resolution of the reference image labeled with MTF₁ is obtained by processing MTFₙ.

In step 4, a to-be-checked light-permeable thin film is located between the testing pattern and the lens, and a testing image of the testing pattern is obtained with the image sensor.

The step 4 is similar to the step 2. The to-be-checked light-permeable thin film takes the place of the reference light-permeable thin film 8. The image sensor 10 obtains a testing image of the testing pattern 7 through the to-be-checked light-permeable thin film.

In step 5, the resolution of the testing image is determined by a modulation transfer function.

The resolution of the testing image is also determined by an MTF. The testing image is also divided into for example 2ⁿ regions. The resolution of each region labeled with MTFₙ is determined. Therefore, the resolution of the testing image labeled with MTF₂ is obtained by processing MTFₙ.

In step 6, the resolution of the testing image is compared with that of the reference image, if the result is in the range of the criterion the to-be-checked light-permeable thin film is passed, if not it is rejected.

The resolution MTF₁ of the reference image is compared with the resolution MTF₂ of the testing image. If value of (MTF₁−MTF₂)/MTF₁ is in the predetermined range, for example 0˜0.2%, the to-be-checked light-permeable thin film is passed, if not it is failed.

If the to-be-checked light-permeable thin film has no flaws, the value of MTF₂ is equal to that of MTF₁ and the value of MTF₁ subtracted MTF₂ will be equal to zero. If the to-be-checked light-permeable thin film has flaws such as dirt particles, scuffing, or water waves, the value of MTF₂ will be smaller than that of MTF₁ and the value of MTF₁ subtracted MTF₂ will be larger than zero. If the to-be-checked light-permeable thin film has fewer flaws, the value of MTF₂ should approximate to that of MTF₁. If not, then the to-be-checked light-permeable thin film has more flaws then the value of MTF₂ should differ substantially to that of MTF₁.

The method for testing the quality of light-permeable thin film of this preferred embodiment uses the programmable processing unit 11 to compute the resolution MTF₁ of the reference image of a reference light-permeable thin film and resolution MTF₂ of the testing image of a to-be-checked light-permeable thin film. During the process of testing and computing, the processing unit 11 finishes the process automatically The values of MTF₁ and MTF₂ are specific numbers, therefore the standard operation criteria are fairly simple. Because of this automation even if different operators operate the method there should be no difference in the results obtained.

The method for testing the quality of light-permeable thin film can also check ultraviolet ray filters or infrared ray cut filters.

Although the present invention has been described with reference to specific embodiments, it should be noted that the described embodiments are not necessarily exclusive, and that various changes and modifications may be made to the described embodiments without departing from the scope of the invention as defined by the appended claims.

What is claimed is:

1. A method for testing the quality of light-permeable thin film, comprising the steps of:
providing a testing pattern;
obtaining an image of the testing pattern as a reference image with an image sensor through a reference light-permeable thin film;
determining resolution of the reference image by a modulation transfer function;
obtaining an image of the testing pattern as a testing image with the image sensor through a to-be-checked light-permeable thin film;
determining resolution of the testing image by a modulation transfer function;
comparing the determined resolution of the testing image with that of the reference image so as to decide whether the to-be-checked light-permeable thin film is flawed.

2. The method as claimed in claim 1, wherein the reference image and the testing image each define a plurality of regions, the resolution of each region is determined by the modulation transfer function.

3. The method as claimed in claim 1, further comprising the steps of transmitting the reference image and the testing images to a processing unit and determining the resolution of the reference image and the testing image by a program installed in the processing unit.

4. The method as claimed in claim 3, wherein the processing unit is chosen from the group consisting of computers and image analyzers.

5. The method as claimed in claim 1, further comprising the step of disposing the reference light-permeable thin film between the testing pattern and the image sensor.

6. The method as claimed in claim 1, further comprising the step of disposing the to-be-checked light-permeable thin film between the testing pattern and the image sensor.

7. The method as claimed in claim 1, wherein the image sensor is chosen from the group consisting of charge coupled devices and complementary metal-oxide semiconductors.

8. The method as claimed in claim 1, wherein the testing pattern is chosen from the group consisting of sinusoidal and square waves.

9. A method for testing the quality of light-permeable thin film, comprising the steps of
providing a testing pattern;
obtaining an image of the testing pattern as a reference image with an image sensor through a reference light-permeable thin film;
determining resolution of the reference image by a contrast transfer function;
obtaining an image of the testing pattern as a testing image with the image sensor through a to-be-checked light-permeable thin film;
determining resolution of the testing image by a contrast transfer function;
comparing the determined resolution of the testing image with that of the reference image so as to decide whether the to-be-checked light-permeable thin film is flawed.
